(19) United States
(12) Patent Application Publication
(10) Pub. No.: US 2007/0006997 A1
(43) Pub. Date: Jan. 11, 2007

(54) Heat sink structure

(75) Inventor: Sung-Chih Hsieh, Taipei City (TW)

Correspondence Address: BIRCH, STEWART, KOLASCH & BIRCH, LLP, 8110 GATEHOUSE ROAD, SUITE 100 EAST, FALLS CHURCH, VA, 22315, US

(73) Assignee: AMA Precision Inc.

(21) Appl. No.: 11/480,883

(22) Filed: Jul. 6, 2006

(30) Foreign Application Priority Data
Jul. 7, 2005 (TW) 094123033

(51) Int. Cl. H05K 7/20

(52) U.S. Cl. 165/104.33; 165/80.3; 361/700

(57) ABSTRACT

A heat sink has a first vent and a second vent. The heat sink includes at least a first heat-dissipating fin having a first wall positioned at the first vent.

### BACKGROUND OF THE INVENTION

1. Field of the Invention

The present invention relates to a heat sink, and more particularly, to a heat sink with heat-dissipating fins each having a wall.

2. Description of the Prior Art

Electronic elements, such as a CPU or a graphics chip in a computer, generate a great amount of heat when they operate, resulting in a high temperature. A heat sink, therefore, can be used to perform the important task of heat dissipating. In general, a heat sink is a combination of a plurality of heat-dissipating fins, which work together with an additional fan for forcing heat accumulated on the fins to be taken away. Please refer to FIG. 1. FIG. 1 is a perspective view of a conventional heat sink 10. In the prior art, through directly contacting an element, e.g. a CPU (not shown in FIG. 1), the element can be heat-dissipated with a heat-dissipating seat 13 of the heat sink 10 and other additional supplementary heat-guiding devices (e.g. a heat pipe 14) for guiding the heat generated from the operating element to a conventional heat-dissipating fin set 11, which is composed of a plurality of heat dissipating fins. Finally, through an airflow driven by rotation of a heat-dissipating fan, the heat accumulated on the heat-dissipating fin is taken away to achieve the heat-dissipating purpose. Please note that the heat-dissipating fin set 11 serves as a kind of impedance (or drag) for the flow of air. Therefore, when the air flows through the heat-dissipating fin set 11, the airflow will choose to pass through the shortest path, i.e. a path with the lowest impedance. As a result, the airflow passes vents located at both sides of the heat-dissipating fin set 11.

The airflow has the above-mentioned characteristic of choosing the path with the lowest impedance to pass through, which can cause a major problem—the airflow may not be able to pass through the center of the heat-dissipating fin set 11, which is the hottest part of the heat-dissipating fin set 11 and therefore particularly needs to be heat-dissipated. Please refer to FIG. 2. FIG. 2 is a cross-sectional view of the heat sink 10 shown in FIG. 1. As shown in FIG. 2, the conventional heat sink 10 has a first vent 15 and a second vent 16. Since a hub of the heat-dissipating fan is an area having no airflow passing through, a windless region 17 exists inside the heat-dissipating fin set 11. This causes the hottest part of the heat-dissipating fin set 11, and most in need of heat dissipation, to have little heat taken away from it as no airflow passes through. As a result, the heat-dissipating performance of the conventional heat sink 10 is degraded.

### SUMMARY OF THE INVENTION

It is therefore one objective of the claimed invention to provide a heat sink with heat-dissipating fins, each having a wall, to solve the above-mentioned problem.

According to one embodiment of the claimed invention, a heat sink is disclosed. The heat sink comprises a first vent and a second vent, and further comprises at least a first heat-dissipating fin, having a first wall located at the first vent of the heat sink.

According to another embodiment of the claimed invention, a heat sink is disclosed. The heat sink comprises a first vent and a second vent, and further comprises at least a first heat-dissipating fin, having a first wall located at the first vent of the heat sink; and at least a second heat-dissipating fin, having a second wall located at the second vent of the heat sink.

According to another embodiment of the claimed invention, a heat sink is disclosed. The heat sink comprises a first vent and a second vent. The heat sink further comprises at least a first heat-dissipating fin, having a first wall located at the first vent of the heat sink, wherein the first heat-dissipating fin comprises an auxiliary vent structure having a third vent and a fourth vent.

The heat-dissipating fin of the claimed invention improves on the vent structure of the prior art, which ventilates at both sides of the heat-dissipating fin. In the claimed invention, when manufacturing the heat-dissipating fin by a punching process, the process also folds up an edge of a vent of the heat-dissipating fin to form a wall, which forces the airflow to ventilate toward the other side of the heat-dissipating fin (the other vent). Through ventilating in a single direction as described, the airflow is capable of passing through the center of the heat-dissipating fin, which is the hottest part, achieving the desired heat exchanging effect. In conclusion, the heat sink with heat-dissipating fins each having a wall is able to optimize the heat-dissipating efficiency of the heat-dissipating fin.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view of a conventional heat sink.

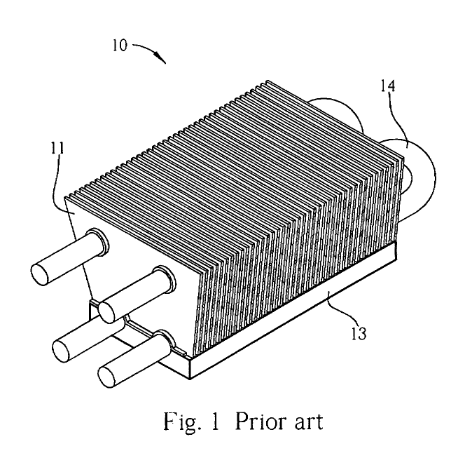

FIG. 2 is a cross-sectional view of the heat sink shown in FIG. 1.

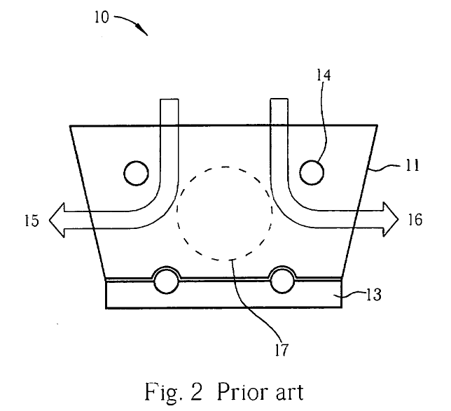

FIG. 3 is a perspective view of a heat sink according to an embodiment of the present invention.

FIG. 4 is a diagram illustrating structure of a heat-dissipating fin set shown in FIG. 3.

FIG. 5 is a diagram illustrating a flowing direction of an airflow when a first heat-dissipating fin shown in FIG. 4 dissipates heat.

FIG. 6 is a diagram illustrating a flowing direction of an airflow when a second heat-dissipating fin shown in FIG. 4 dissipates heat.

FIG. 7 is a diagram illustrating structure of a heat-dissipating seat shown in FIG. 3.

FIG. 8 is a perspective view of a heat-dissipating fin set according to another embodiment of the present invention.

FIG. 9 is a diagram illustrating a flowing direction of an airflow when a third heat-dissipating fin shown in FIG. 8 dissipates heat.

FIG. 10 is a diagram illustrating a flowing direction of an airflow when a fourth heat-dissipating fin shown in FIG. 8 dissipates heat.

### DETAILED DESCRIPTION

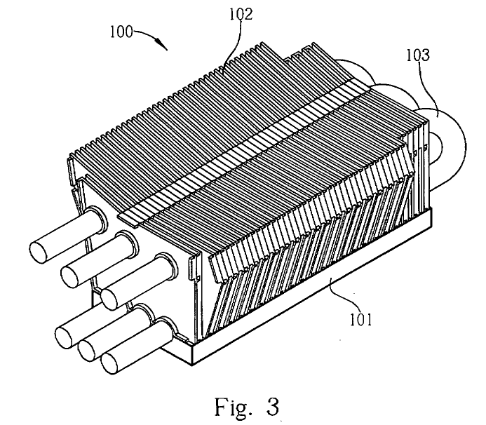

Please refer to FIG. 3. FIG. 3 is a perspective view of a heat sink 100 according to an embodiment of the present invention. In this embodiment, the heat sink 100 comprises a heat-dissipating fin set 102 and at least a heat pipe 103 to assist in guiding heat accumulated on a heat-dissipating seat 101 to the heat-dissipating fin set 102. Please note that the number of heat-dissipating fins of the heat-dissipating fin set 102 and the number of the heat pipe 103 are only used as examples, and are not meant to be taken as limitations of the present invention. The difference between the heat sink 100 of the present invention and the prior art heat sink is the structure of the heat-dissipating fin 102 which will be detailed as follows.

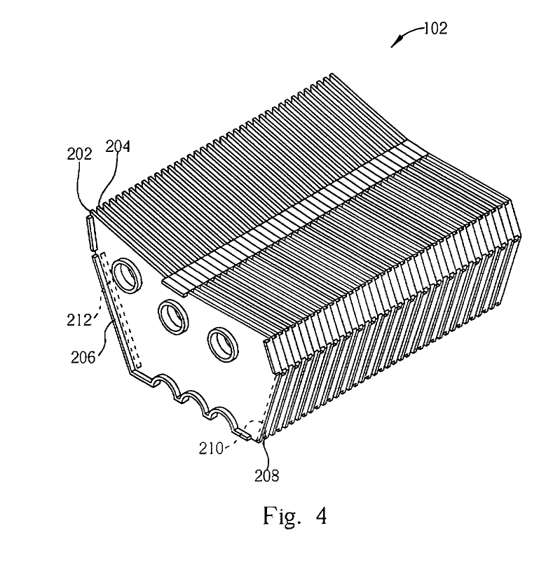

Please refer to FIG. 4. FIG. 4 is a diagram illustrating structure of the heat-dissipating fin set 102 shown in FIG. 3. The heat-dissipating fin set 102 comprises a plurality of first heat-dissipating fins 202 and a plurality of second heat-dissipating fins 204. Please note that a first wall 206 is formed at a first vent of the first heat-dissipating fin 202, while a second wall 208 is formed at a second vent of the second heat-dissipating fin 204. The first wall 206 can be directly punched from the first heat-dissipating fin 202; however, the first wall 206 can also be an independent element connected to the first heat dissipating fin 202. For example, the first wall 206 can be connected to the first heat dissipating fin 202 through a pivot or other available means. Moreover, the first wall 206 only serves as a drag element disposed between every two heat-dissipating fins. In a preferred embodiment, the heat-dissipating fins are arranged alternatively, that is, a first of the plurality of second heat-dissipating fins is disposed next to a first of the plurality of first heat-dissipating fins, and then a second of the plurality of second heat-dissipating fins is disposed next to a second of the plurality of first heat-dissipating fins. Following the arrangement rule, a heat-dissipating fin set is formed. In this embodiment the first wall can be located at the front side of the first of the plurality of first heat-dissipating fins, or between the first of the plurality of second heat-dissipating fins and the second of the plurality of first heat-dissipating fins. That is, in this embodiment, there is a first wall between each of-the first heat-dissipating fins and its corresponding second heat-dissipating fin disposed before it. Similarly, there is a second wall between each of the second heat-dissipating fins and its corresponding first heat-dissipating fin disposed before it. Please note that each first wall is located at the first vent of the heat sink and each second wall is located at the second vent of the heat sink in order to guide wind to ventilate from the desired vents.

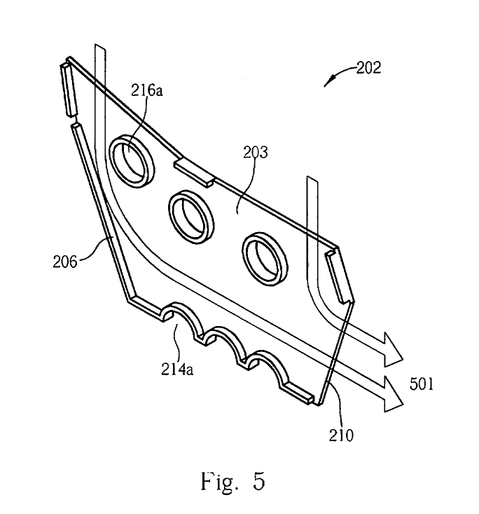

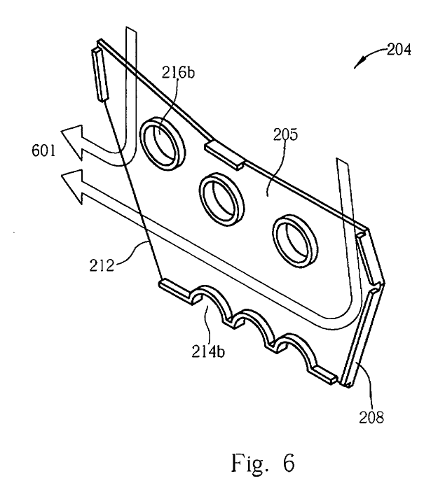

Next, please refer to FIG. 5. FIG. 5 is a diagram illustrating a flowing direction of an airflow when a first heat-dissipating fin 202 shown in FIG. 4 dissipates heat. When carrying out heat-dissipation, a wind blows into the heat sink from the top of the heat sink and induces an airflow. The airflow will then flow along a seam defined in the first heat-dissipating fin 202, and flow out of the heat sink through a relatively low drag direction. The direction of the arrow 501 is caused by the existence of the first wall 206 at the first vent, which makes the drag higher. When the airflow guided into the heat sink by the heat-dissipating fin flows in the seam of the heat-dissipating fin, the first wall 206 will have a relatively higher drag, causing the airflow to return to a second vent 210 after reaching the first wall 206 and bring out heat accumulated on the corresponding first heat-dissipating fin 202. It should be noted that in the prior art, the center of the heat-dissipating fin set has a windless region, but in the present invention, the airflow (indicated by arrow 501) can pass through the windless region of the prior art and bring away the accumulated heat. Therefore, the heat sink of the present invention has better heat-dissipating efficiency. Similarly, FIG. 6 is a diagram illustrating a flowing direction of the airflow when the second heat-dissipating fin 204 shown in FIG. 4 dissipates heat. When the heat sink is carrying out heat-dissipation, a wind blows into the heat sink from the top of the heat sink, and then induces an airflow flowing along the seam of the second heat-dissipating fin 204 and leaving the second heat-dissipating fin 204 through a relatively low drag direction as shown by an arrow 601. Therefore, the heat sink of the present invention has better heat-dissipating efficiency.

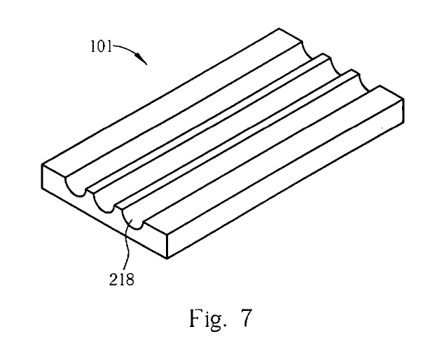

Please refer to FIG. 7 in conjunction with FIG. 5 and FIG. 6. FIG. 7 is a diagram illustrating a structure of the heat-dissipating seat 101 shown in FIG. 3. The surface of the heat-dissipating seat 101 has a plurality of slots 218 formed thereon according to a desired number and desired installation positions of the heat pipe 103. Similarly, as shown in FIG. 5 and FIG. 6, in accordance with the number and the installation positions of the heat pipe 103, the bottoms of the first and the second heat-dissipating fins 202 and 204 have hollow parts 214a and 214b respectively, and holes 216a and 216b are formed on the upper parts of the first and the second heat-dissipating fins 202 and 204. That is, the slot 218, the hollow parts 214a and 214b, and the holes 216a and 216b are used to install the heat pipe 103 for distributing the heat accumulated by the heat-dissipating seat 101 from the element to be heat-dissipated to each of the first and the second heat dissipating fins 202 and 204 of the heat-dissipating fin set 102.

As mentioned above, the first and the second heat dissipating fins 202 and 204 are arranged alternatively on the heat-dissipating seat 101. As shown in FIG. 5 and FIG. 6, the wall 206 of the first heat-dissipating fin 202 is disposed at the first vent of the heat-dissipating seat 101, and the wall 208 of the first heat-dissipating fin 204 is disposed at the second vent of the heat-dissipating seat 101. In other words, the airflow guided into the heat sink by the heat-dissipating fan will be guided out from the second vent 210 and the first vent 212, alternatively. In other words, the first heat-dissipating fin 202 and the second heat-dissipating fin 204 will generate a plurality of heat-dissipating channels since they are arranged alternatively. This arrangement will make the first and the second heat-dissipating fins 202 and 204 dissipate heat more uniformly, substantially improving the heat-dissipating efficiency of the heat sink 100.

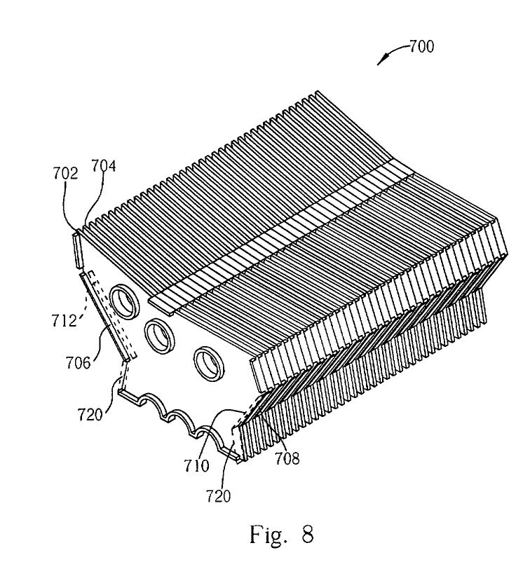

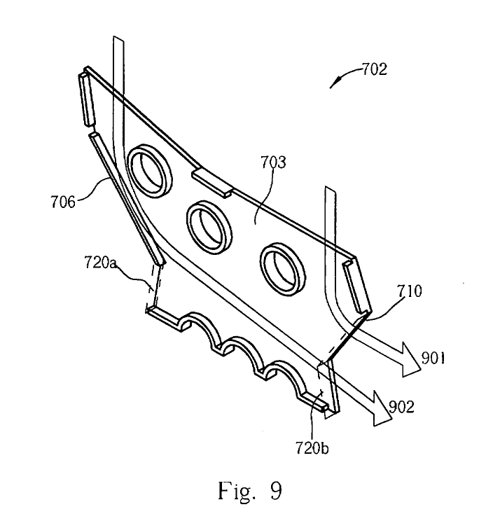

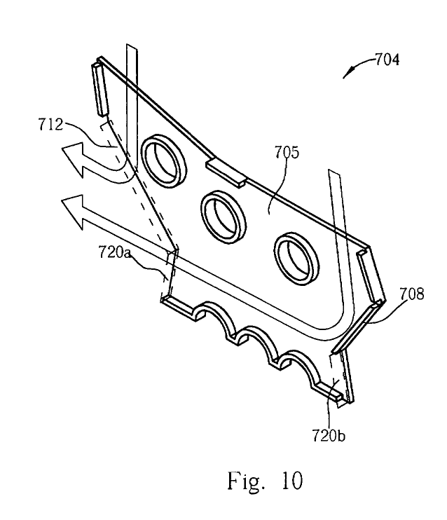

Please refer to FIG. 3, FIG. 8, FIG. 9, and FIG. 10. FIG. 8 is a perspective view of a heat-dissipating fin set 700 according to another embodiment of the present invention. FIG. 9 is a diagram of a flowing direction of an airflow when a third heat-dissipating fin 702 shown in FIG. 8 dissipates heat. FIG. 10 is a diagram of a flowing direction of an airflow when a fourth heat-dissipating fin 704 shown in FIG. 8 dissipates heat. In this embodiment, the heat-dissipating fin set 700 comprises an auxiliary ventilating structure. As shown in FIG. 8, the heat-dissipating fin set 700 comprises a plurality of third heat-dissipating fins 702 and a plurality of fourth heat-dissipating fins 704. In an embodiment, the plurality of third heat-dissipating fins 702 and the plurality of fourth heat-dissipating fins 704 can be arranged alternatively; however, please note that the present invention is not limited to this arrangement. For example, three fourth heat-dissipating fins can be disposed following two third heat-dissipating fins. Moreover, in order to fix the third and the fourth heat-dissipating fins 702 and 704 on a heat-dissipating seat (not shown), the present invention makes use of solder to weld the third and the fourth heat-dissipating fins 702 and 704 and the heat-dissipating seat (not shown). The heat-dissipating fin set 700 further comprises a plurality of walls 706 and 708 formed from the punching process that forms the third and the fourth heat-dissipating fins 702 and 704, where an auxiliary ventilating structure is formed at the bottom. In this embodiment, for both the third and fourth heat-dissipating fins 702 and 704, only one side of a heat-dissipating slice 703, 705 has walls 706, 708 respectively disposed thereon, while the other side and the bottom define a vent 710, 712 respectively. Moreover, compared with the first and the second heat-dissipating fins 202 and 204 in the aforementioned embodiment, the heat-dissipating slices 703 and 705 in this embodiment comprise an auxiliary ventilating structure. For clarity and simplicity, the third heat-dissipating fin 702 is taken as an example. Referring to FIG. 9, in this embodiment, there is an auxiliary ventilating structure formed under the wall 706. The structure can be in a conventional heat-dissipating fin structure, comprising vents at both sides, with reserved places for installing heat pipes at the bottom of the fin. As shown in FIG. 9, three heat pipe holes are formed. Please note the number of heat pipe holes is not meant to be a limitation of the present invention.

In this embodiment, during operation, the heat-dissipating fan (not shown) blows the air (arrows shown in FIG. 9 and FIG. 10) in a top-to-bottom direction into the structure of the heat-dissipating fin set 700. Therefore, the airflow will flow between seams defined by the third and the fourth heat-dissipating fins 702 and 704, and flow away through the relatively low impedance (drag) part of the heat-dissipating fin set 700. However, when the airflow guided by the heat-dissipating fan flows between the third and the fourth heat-dissipating fins 702 and 704 and reaches the walls 706, 708, the walls 706 and 708 will guide the airflow to ventilate through vents 710 and 712 on the other side, as the walls 706 and 708 constitute a relatively high drag. The bottom vents 720a and 720b will bring away the heat on the third and the fourth heat dissipating fins 702 and 704, which is absorbed by the heat-dissipating seat 101. Through this process, the airflow will pass the center of the heat-dissipating fin set 700 and bring away the heat which cannot easily be dissipated in the prior art, due to the conventional structure having little airflow passing through. Through the existence of the vents 720a and 720b, the ventilation of the airflow is forced, generated by the heat-dissipating fan, at the bottom of the heat-dissipating fin set 700, thus further improving the heat-dissipating efficiency of the heat sink of the present invention. Therefore, compared with the prior art heat sink, the heat sink of the present invention has better heat-dissipating efficiency. Furthermore, referring to FIG. 9, because of the existence of the wall 706, the left side has greater drag and an airflow direction indicated by an arrow 901 will be guided to the vent (the second vent 710) at the right side. Similarly, when the airflow is greater, the left side has greater drag and, as indicated by an arrow 902, the airflow can be further ventilated by the auxiliary ventilating structure (the fourth vent 720b). Please note that the airflow indicated by arrow 902 can also be ventilated by the second vent 710. Certainly, when the drag of the second vent 710 is greater, the airflow indicated by arrow 902 will choose the relatively low drag path (the fourth vent 720b) for ventilating. More specifically, in this embodiment, because the wall 706 is not completely airtight, there is still some airflow that can be ventilated from the third vent 720a.

As mentioned above, in this embodiment the third and the fourth heat-dissipating fins 702 and 704 are alternatively arranged on the heat-dissipating seat 101, and, as shown in FIG. 9 and FIG. 10, the wall 706 of the third heat-dissipating fin 702 is disposed at a first side of the heat-dissipating seat 101, and the wall 708 of the second heat-dissipating fin 704 is disposed at a second side of the heat-dissipating seat 101. In other words, the airflow guided into the heat sink by the heat-dissipating fan will be guided out of the heat sink from the vents 710 and 712 alternatively. In other words, in this embodiment, the third heat-dissipating fin 702 and the third heat-dissipating fin 704 will alternatively generate a plurality of ventilating heat-dissipating channels due to their special arrangement. Therefore, the arrangement can make the third and the fourth heat-dissipating fins 702 and 704 dissipate heat uniformly. In addition, with the help of the bottom vents 720a and 720b to force the ventilation of airflows, the heat sink 100 with the heat-dissipating fin set 700 installed can greatly improve the heat-dissipating efficiency. More specifically, in an embodiment, the third and the fourth heat-dissipating fins 702 and 704 can further comprise a third wall disposed at the vent 710 of the third heat-dissipating fin 702 and a fourth wall disposed at the vent 712 of the third heat-dissipating fin 704. Therefore, the airflow guided into the heat sink by the heat-dissipating fan will ventilate through the bottom vents 720a and 720b.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A heat sink, having a first vent and a second vent, comprising:
at least a first heat-dissipating fin, having a first wall positioned at the first vent of the heat sink.

2. The heat sink of claim 1, further comprising:
at least a second heat-dissipating fin, having a second wall positioned at the second vent of the heat sink.

3. The heat sink of claim 2, wherein first heat-dissipating fins and second heat-dissipating fins are arranged alternatively in the heat sink.

4. The heat sink of claim 1, further comprising:
a heat-dissipating seat and at least a heat pipe, wherein the heat pipe is coupled to the heat-dissipating seat.

5. The heat sink of claim 1, wherein the first heat-dissipating fin comprises an auxiliary ventilating structure, and the auxiliary ventilating structure has a third vent and a fourth vent.

6. A heat sink, having a first vent and a second vent, comprising:
at least a first heat-dissipating fin, having a first wall positioned at the first vent of the heat sink; and
at least a second heat-dissipating fin, having a second wall positioned at the second vent of the heat sink.

7. The heat sink of claim 6, wherein first heat-dissipating fins and second heat-dissipating fins are arranged alternatively in the heat sink.

8. The heat sink of claim 6, further comprising:
a heat-dissipating seat and at least a heat pipe, wherein the heat pipe is coupled to the heat-dissipating seat.

9. The heat sink of claim 6, wherein the first heat-dissipating fin comprises an auxiliary ventilating structure, and the auxiliary ventilating structure has a third vent and a fourth vent.

10. A heat sink, having a first vent and a second vent, comprising:
at least a first heat-dissipating fin, having a first wall located at the first vent of the heat sink;
wherein the first heat-dissipating fin comprises an auxiliary ventilating structure, and the auxiliary ventilating structure has a third vent and a fourth vent.

11. The heat sink of claim 10, further comprising:
at least a second heat-dissipating fin, having a second wall positioned at the second vent of the heat sink.

12. The heat sink of claim 11, wherein first heat-dissipating fins and second heat-dissipating fins are arranged alternatively in the heat sink.

13. The heat sink of claim 1 1, wherein the first heat-dissipating fin and the second heat-dissipating fin further comprise a third wall positioned at the second vent of the first heat-dissipating fin and a fourth wall positioned at the first vent of the second heat-dissipating fin.
